(19) United States
(12) Patent Application Publication
(10) Pub. No.: US 2024/0069451 A1
(43) Pub. Date: Feb. 29, 2024

(54) SUPERCRITICAL FLUID SUPPLY APPARATUS, SUBSTRATE PROCESSING APPARATUS INCLUDING THE SAME, AND SUBSTRATE PROCESSING METHOD USING THE SAME

(71) Applicant: Samsung Electronics Co., Ltd., Suwon-si (KR)

(72) Inventors: SANGJINE PARK, Suwon-si (KR); Ji Hwan PARK, Suwon-si (KR); KUNTACK LEE, Suwon-si (KR)

(21) Appl. No.: 18/130,001

(22) Filed: Apr. 3, 2023

(30) Foreign Application Priority Data
Aug. 24, 2022 (KR) 10-2022-0105966

(51) Int. Cl. G03F 7/00; G03F 7/16

(52) U.S. Cl. CPC G03F 7/70808; G03F 7/168

(57) ABSTRACT

Disclosed are supercritical fluid supply apparatuses, substrate processing apparatuses, and substrate processing methods. The substrate processing apparatus comprises a dry chamber including a dry space configured in which to dispose a substrate, and a supercritical fluid supply apparatus configured to supply the dry chamber with a supercritical fluid. The supercritical fluid supply apparatus includes a fluid supply tank, a high-temperature fluid tank configured in which to store a fluid supplied from the fluid supply tank at a first temperature, and a low-temperature fluid tank configured in which to store a fluid supplied from the fluid supply tank at a second temperature different from the first temperature. The high-temperature fluid tank and the low-temperature fluid tank are connected in parallel between the fluid supply tank and the dry chamber.

### CROSS-REFERENCE TO RELATED APPLICATION

This U.S. nonprovisional application claims priority under 35 U.S.C § 119 to Korean Patent Application No. 10-2022-0105966 filed on Aug. 24, 2022 in the Korean Intellectual Property Office, the disclosure of which is hereby incorporated by reference in its entirety.

### BACKGROUND

The present inventive concepts relate to a supercritical fluid supply apparatus, a substrate processing apparatus including the same, and a substrate processing method using the same, and more particularly, to a supercritical fluid supply apparatus capable of promptly controlling the temperature of a supercritical fluid supplied to a dry chamber, a substrate processing apparatus including the same, and a substrate processing method using the same.

A semiconductor device may be fabricated through various processes. For example, the semiconductor device may be manufactured through a photolithography process, an etching process, a deposition process, and a plating process. During a photolithography process for fabricating a semiconductor device, a wet process may be performed to coat liquid, such as a developer, on a wafer. In addition, a dry process may be performed/executed to remove/dry the liquid coated on the wafer. Various methods may be used to coat the liquid on the wafer or to remove the layer from the wafer.

### SUMMARY

Some embodiments of the present inventive concepts provide a supercritical fluid supply apparatus capable of promptly controlling the temperature of a supplied supercritical fluid, a substrate processing apparatus including the same, and a substrate processing method using the same.

Some embodiments of the present inventive concepts provide a supercritical fluid supply apparatus capable of allowing a supercritical fluid to change its temperature supplied during a process, a substrate processing apparatus including the same, and a substrate processing method using the same.

Some embodiments of the present inventive concepts provide a supercritical fluid supply apparatus capable of quickly coping with various recipes, a substrate processing apparatus including the same, and a substrate processing method using the same.

The object of the present inventive concepts is not limited to the ones mentioned above, and other objects which have not been mentioned above will be clearly understood to those skilled in the art from the following description.

According to some embodiments of the present inventive concepts, a substrate processing apparatus may comprise: a dry chamber including a dry space configured in which to dispose a substrate; and a supercritical fluid supply apparatus configured to supply the dry chamber with a supercritical fluid. The supercritical fluid supply apparatus may include: a fluid supply tank; a high-temperature fluid tank configured in which to store a fluid supplied from the fluid supply tank at a first temperature; and a low-temperature fluid tank configured in which to store a fluid supplied from the fluid supply tank at a second temperature different from the first temperature. The high-temperature fluid tank and the low-temperature fluid tank may be connected in parallel between the fluid supply tank and the dry chamber.

According to some embodiments of the present inventive concepts, a supercritical fluid supply apparatus may comprise: a fluid supply tank; a condenser connected to the fluid supply tank; a pump connected to the condenser; a high-temperature fluid tank connected to the pump; a low-temperature fluid tank connected to the pump; and a mixer configured to mix a fluid coming from the high-temperature fluid tank with a fluid coming from the low-temperature fluid tank. The fluid supply tank, the condenser, and the pump may be connected in series with each other. The high-temperature fluid tank and the low-temperature fluid tank may be connected in parallel between the pump and the mixer. The high-temperature fluid tank is configured to store a fluid supplied from the fluid supply tank at a first temperature. The low-temperature fluid tank is configured to store a fluid supplied from the fluid supply tank at a second temperature. The second temperature may be different from the first temperature.

According to some embodiments of the present inventive concepts, a substrate processing method may comprise: performing a wet process on a substrate; and performing a dry process on the substrate that has been processed with the wet process. The step of performing the dry process on the substrate may include: placing the substrate into a dry chamber; and supplying the dry chamber with a dry fluid from a supercritical fluid supply apparatus. The step of supplying the dry chamber with the dry fluid may include: supplying a high-temperature fluid from a high-temperature fluid tank; supplying a low-temperature fluid from a low-temperature fluid tank; and supply the dry chamber with the dry fluid formed by mixing the high-temperature fluid and the low-temperature fluid with each other.

Details of other example embodiments are included in the description and drawings.

### BRIEF DESCRIPTION OF THE DRAWINGS

FIG. 1 illustrates a simplified schematic diagram showing a substrate processing apparatus according to some embodiments of the present inventive concepts.

FIG. 2 illustrates a cross-sectional view showing a wet chamber according to some embodiments of the present inventive concepts.

FIG. 3 illustrates a cross-sectional view showing a dry chamber according to some embodiments of the present inventive concepts.

FIG. 4 illustrates a simplified schematic diagram showing a supercritical fluid supply apparatus according to some embodiments of the present inventive concepts.

FIG. 5 illustrates an exploded perspective view showing a high-temperature fluid tank according to some embodiments of the present inventive concepts.

FIG. 6 illustrates a perspective view showing a mixer according to some embodiments of the present inventive concepts.

FIG. 7 illustrates a flow chart showing a substrate processing method according to some embodiments of the present inventive concepts.

FIGS. 8 to 14 illustrate diagrams showing a substrate processing method according to the flow chart of FIG. 7.

FIG. 15 illustrates a simplified schematic diagram showing a supercritical fluid supply apparatus according to some embodiments of the present inventive concepts.

FIG. 16 illustrates a simplified schematic diagram showing a supercritical fluid supply apparatus according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

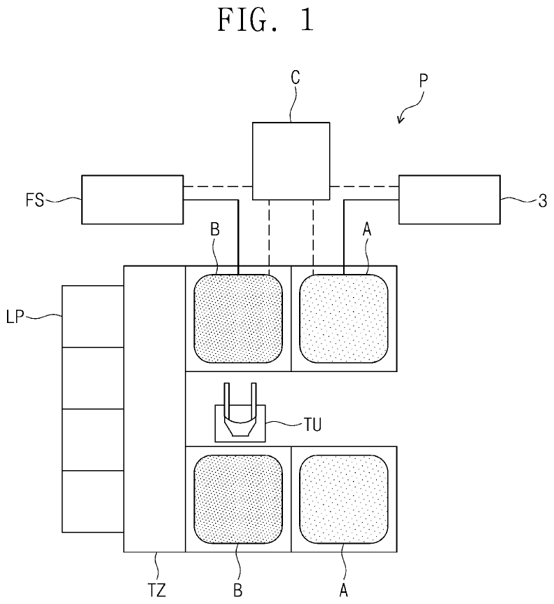

FIG. 1 illustrates a simplified schematic diagram showing a substrate processing apparatus according to some embodiments of the present inventive concepts.

Referring to FIG. 1, a substrate processing apparatus P may be provided. The substrate processing apparatus P may be a device to treat a substrate in semiconductor fabrication process. The substrate processing apparatus P may be configured to perform/execute a wet process and a dry process on a substrate. A wet process may be a process coating a liquid on a substrate and/or cleaning the substrate with a cleaning liquid. For example, the substrate processing apparatus P may provide a substrate with liquid to wet the substrate or may remove liquid from a substrate to dry and/or clean the substrate. The substrate processing apparatus P may spray a developer on a substrate that has experienced (e.g., been processed with) an extreme ultraviolet (EUV) exposure process. The substrate processing apparatus P may dry a developer on a substrate. In this description, the term “substrate” may indicate a semiconductor wafer. The wafer may include a silicon (Si) wafer, but the present inventive concepts are not limited thereto. The substrate processing apparatus P may include a loading port LP, a transfer zone TZ, a wet chamber B, a wetting solution supply apparatus FS, a transfer unit TU, a dry chamber A, a supercritical fluid supply apparatus 3, and a controller C.

The loading port LP may be a port on which a substrate is loaded. For example, the loading port LP may load thereon a substrate that has experienced (e.g., been processed with) various semiconductor fabrication processes. A plurality of loading ports LP may be provided in the substrate processing apparatus P. A plurality of substrates may be respectively loaded on the plurality of loading ports LP. One loading port LP is discussed in the present disclosure as an example and the one loading port LP represents each of the loading ports LP unless otherwise specifically noted.

The transfer zone TZ may be a region where a substrate loaded on the loading port LP is transferred. For example, the transfer unit TU may transfer a substrate loaded on the loading port LP to the wet chamber B and/or the dry chamber A. For example, the transfer unit TU may transfer substrates from the loading port LP to the chambers (e.g., the wet chamber B and/or the dry chamber A) through the transfer zone TZ. The transfer zone TZ may cover a plurality of loading ports LP. For example, the transfer zone TZ may be connected/open to a plurality of loading ports LP.

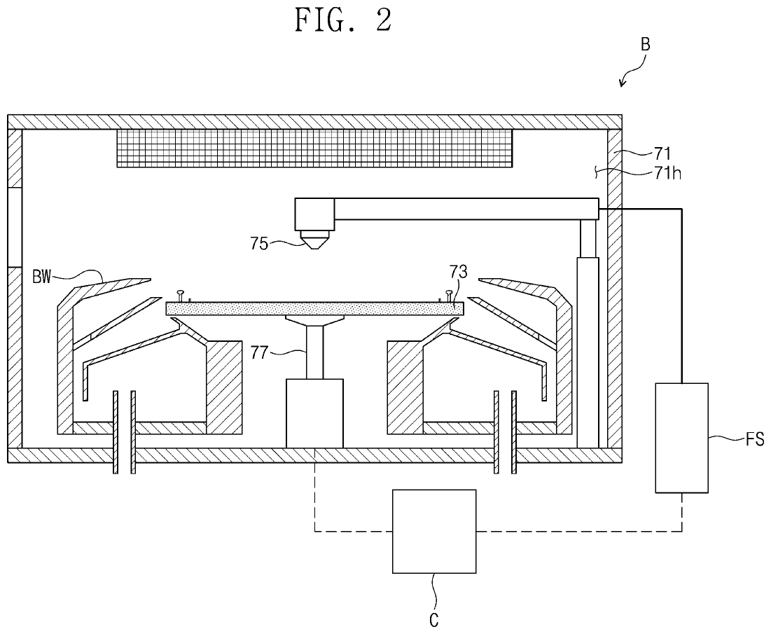

The wet chamber B may be a chamber in which a substrate undergoes a wet process. The wet chamber B may provide a space where a wet process is performed. When a substrate is disposed in the wet chamber B, the substrate may be coated thereon with liquid, such as various chemicals and/or isopropyl alcohol (IPA). The liquid coating may be fulfilled in various ways. For example, a liquid may be sprayed on a substrate that rotates, and a centrifugal force may cause/move the liquid to uniformly distribute on the substrate. A plurality of wet chambers B may be provided in the substrate processing apparatus P. For example, two wet chambers B may be provided in the substrate processing apparatus P. The two wet chambers B may be disposed to face each other. A single wet chamber B, however, will be discussed below, which represents each of the wet chambers B unless otherwise specified. The wet chamber B will be further discussed in detail below with reference to FIG. 2.

The wetting solution supply apparatus FS may supply the wet chamber B with fluid. The wetting solution supply apparatus FS may include a fluid tank, a pump, and so forth. A fluid that the wetting solution supply apparatus FS supplies to the wet chamber B may be called as a wetting solution. The wetting solution may include various chemicals and/or water. For example, the wetting solution may include or may be a developer or isopropyl alcohol (IPA).

The transfer unit TU may transfer a substrate. For example, the transfer unit TU may transfer a substrate loaded on the loading port LP through the transfer zone TZ to the wet chamber B. For example, the transfer unit TU may unload a substrate from the wet chamber B, and may then transfer the unloaded substrate to the dry chamber A. The transfer unit TU may include an actuator such as a motor. A single transfer unit TU may be provided in the substrate processing apparatus P, but the present inventive concepts are not limited thereto.

The dry chamber A may be a chamber to dry a substrate. For example, the dry chamber A may dry and/or clean a substrate that has passed through the wet chamber B. For example, the dry chamber A may remove liquid from a substrate on which the liquid, such as a developer and/or isopropyl alcohol (IPA), is coated in the wet chamber B. The dry chamber A may provide a space where a dry process is performed. A plurality of dry chambers A may be provided in the substrate processing apparatus P. For example, two dry chambers A may be provided. The two dry chambers A may be disposed to face each other. A single dry chamber A, however, will be discussed below, which represents each of the dry chambers A unless otherwise specified.

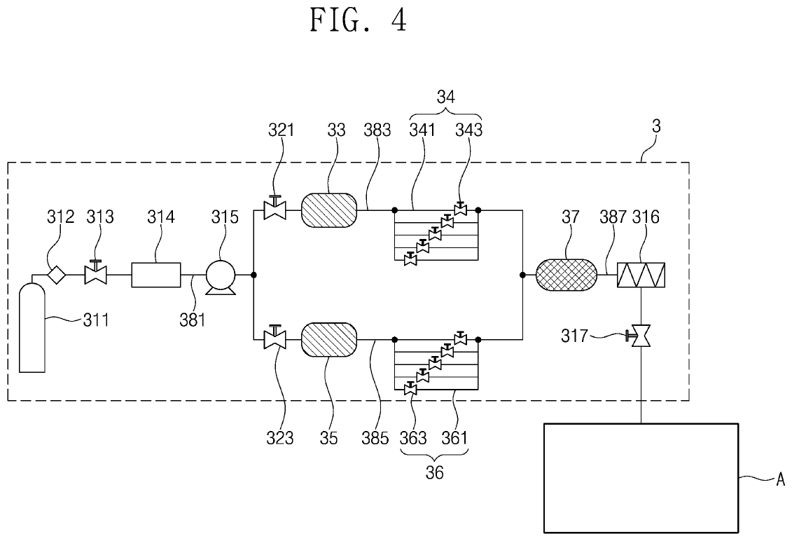

The supercritical fluid supply apparatus 3 may supply the dry chamber A with fluid. For example, the supercritical fluid supply apparatus 3 may supply a supercritical fluid that is sprayed into the dry chamber A. For example, the supercritical fluid supply apparatus 3 may supply the dry chamber A with carbon dioxide (CO₂) in its supercritical fluid (SCF) state. The supercritical fluid supply apparatus 3 will be further discussed in detail below with reference to FIG. 4.

The controller C may control the wet chamber B and the dry chamber A. For example, the controller C may control the supercritical fluid supply apparatus 3 to adjust the degree of dryness of a substrate. For example, the controller C may control temperature and/or flow rate of fluid (e.g., the supercritical fluid) that is supplied to the dry chamber A. A detailed description thereof will be further discussed below. For example, the controller C may be a general controller controlling overall functions of the substrate processing apparatus P.

FIG. 2 illustrates a cross-sectional view showing a wet chamber according to some embodiments of the present inventive concepts.

Referring to FIG. 2, the wet chamber B may include a wet chamber housing 71, a wetting stage 73, a wetting nozzle 75, a rotating shaft 77, and a bowl BW.

The wet chamber housing 71 may provide a wetting space 71h. A wet process may be performed on a substrate disposed in the wetting space 71h.

The wetting stage 73 may be positioned in the wet chamber housing 71, e.g., in a space enclosed by the wet chamber housing 71. The wetting stage 73 may support a substrate. For example, a substrate inserted/loaded in the wet chamber B, e.g., into the space enclosed by the wet chamber housing 71 may be disposed on the wetting stage 73. The wetting stage 73 may rotate a substrate. For example, the wetting stage 73 may rotate when the substrate is loaded on the wetting stage 73, thereby rotating the substrate together with the wetting stage 73 itself.

The wetting nozzle 75 may be upwardly spaced apart from the wetting stage 73. The wetting nozzle 75 may be connected to the wetting solution supply apparatus FS. The wetting nozzle 75 may be supplied with the wetting solution from the wetting solution supply apparatus FS, and may spray the wetting solution toward the wetting stage 73, e.g., when a substrate is loaded on the wetting stage 73.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The controller C may control the rotating shaft 77 to rotate the wetting stage 73. The rotating shaft 77 may drive the wetting stage 73 to rotate, thereby rotating the substrate loaded on the wetting stage 73.

The bowl BW may surround the wetting stage 73. The bowl BW may collect the wetting solution which flows outwardly from the substrate loaded on wetting stage 73. For example, a portion of the wetting solution may fly out from an edge of the substrate to the bowl BW when the substrate rotates. For example, the portion of wetting solution frying out from the edge of the substrate may be surplus wetting solution provided on the substrate.

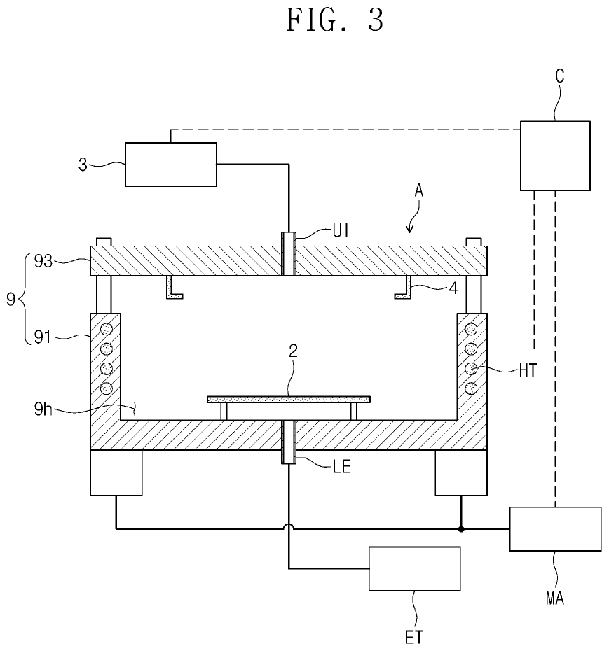

FIG. 3 illustrates a cross-sectional view showing a dry chamber according to some embodiments of the present inventive concepts.

Referring to FIG. 3, the dry chamber A may dry a substrate. For example, the dry chamber A may remove liquid from a substrate. The dry chamber A may dry a substrate that has been wetted in the wet chamber (see B of FIG. 2). The dry chamber A may include a dry chamber housing 9, a dry heater HT, a dry chuck 4, a blocking plate 2, a chamber driving mechanism MA, and an exhaust tank ET.

The dry chamber housing 9 may provide a dry space 9h (e.g., inside the dry chamber housing 9), a fluid supply inlet UI, and a fluid exhaust outlet LE. The dry chamber housing 9 may include a lower chamber 91 and an upper chamber 93. The lower chamber 91 may be downwardly spaced apart from the upper chamber 93, e.g., when the lower chamber 91 and the upper chamber 93 are separated from each other. The dry space 9h may be provided between the lower chamber 91 and the upper chamber 93. The lower chamber 91 may be vertically movable. For example, the chamber driving mechanism MA may drive the lower chamber 91 to move upwardly to combine with the upper chamber 93. The lower chamber 91 and the upper chamber 93 may be combined to separate the dry space 9h from external. For example, the lower chamber 91 may be a lower housing of the dry chamber A, and the upper chamber 93 may be an upper housing of the dry chamber A.

The fluid supply inlet UI may be provided to, for example, the upper chamber 93. The fluid supply inlet UI may be connected to the supercritical fluid supply apparatus 3. A supercritical fluid may be supplied from the supercritical fluid supply apparatus 3 through the fluid supply inlet UI to the dry space 9h. The present inventive concepts, however, are not limited thereto, and the fluid supply inlet UI may be provided to the lower chamber 91.

The fluid exhaust outlet LE may be provided to, for example, the lower chamber 91. The fluid exhaust outlet LE may be connected/attached to the exhaust tank ET. A fluid may be outwardly discharged through the fluid exhaust outlet LE from the dry chamber housing 9 to the outside of the dry chamber housing 9.

The dry heater HT may be coupled to the dry chamber housing 9. The dry heater HT may heat the dry space 9h, e.g., during a drying process. The heating of the dry heater HT may permit a supercritical fluid introduced into the dry space 9h to maintain its supercritical state.

The dry chuck 4 may be connected/attached to the upper chamber 93. The dry chuck 4 may be downwardly spaced apart from the upper chamber 93. A substrate may be disposed on the dry chuck 4. For example, the dry chuck 4 may support a substrate, e.g., while a drying process is performed.

The blocking plate 2 may be connected/attached to the lower chamber 91. The blocking plate 2 may be upwardly spaced apart at a certain interval from the fluid exhaust outlet LE. The blocking plate 2 may block a fluid flow. The chamber driving mechanism MA may be connected to the lower chamber 91. The chamber driving mechanism MA may drive the lower chamber 91 to move vertically. The chamber driving mechanism MA may combine the lower chamber 91 with the upper chamber 93, or may separate the lower chamber 91 from the upper chamber 93. The chamber driving mechanism MA may include an actuator such as a motor. The exhaust tank ET may be connected to the fluid exhaust outlet LE. The exhaust tank ET may receive a fluid that is discharged from the dry space 9h through the fluid exhaust outlet LE.

FIG. 4 illustrates a simplified schematic diagram showing a supercritical fluid supply apparatus according to some embodiments of the present inventive concepts.

Referring to FIG. 4, a supercritical fluid supply apparatus 3 may include a fluid supply tank 311, a first supply pipe 381, a supply filter 312, a first valve 313, a condenser 314, a pump 315, a high-temperature pipe 383, a high-temperature fluid valve 321, a high-temperature fluid tank 33, a high-temperature fluid flow control unit 34, a low-temperature pipe 385, a low-temperature fluid valve 323, a low-temperature fluid tank 35, a low-temperature fluid flow control unit 36, a second supply pipe 387, a mixer 37, a heater 316, and a second valve 317.

The fluid supply tank 311 may store and supply a gaseous fluid which will be a supercritical fluid. When a dry fluid is a carbon dioxide (CO₂) supercritical fluid, the fluid supply tank 311 may store CO₂ in its gaseous state. The gaseous CO₂ supplied from the fluid supply tank 311 may have a temperature of about 10° C. to about 30° C. The gaseous CO₂ supplied from the fluid supply tank 311 may have a pressure of about 4 MPa to about 6 MPa. A fluid supplied from the fluid supply tank 311 may move along the first supply pipe 381.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The first supply pipe 381 may be connected to the fluid supply tank 311. The supply filter 312, the first valve 313, the condenser 314, and the pump 315 may be disposed on the first supply pipe 381. For example, the fluid supply tank 311, the supply filter 312, the first valve 313, the condenser 314, and the pump 315 may be disposed in series on the first supply pipe 381.

The supply filter 312 may filter foreign substances present in fluid. The first valve 313 may control fluid movement by opening or closing a pathway between the supply filter 312 and the condenser 314.

The condenser 314 may cool the gaseous CO₂ supplied from the fluid supply tank 311. Therefore, the gaseous CO₂ may be liquefied in the condenser 314. For example, the CO₂ liquefied in the condenser 314 may have a temperature of about 0° C. to about 6° C. The CO₂ liquefied in the condenser 314 may have a pressure of about 4 MPa to about 6 MPa. The present inventive concepts, however, are not limited thereto, and a fluid that has passed through the condenser 314 may be in a gaseous state and/or a supercritical state.

The pump 315 may increase a pressure of fluid that is liquefied while passing through the condenser 314. For example, the pump 315 may provide a pressure between about 15 MPa and about 25 MPa to the CO₂ liquefied in the condenser 314.

The high-temperature pipe 383 may be connected to the first supply pipe 381. For example, the high-temperature pipe 383 may be branched off from the first supply pipe 381. The high-temperature fluid valve 321, the high-temperature fluid tank 33, and the high-temperature fluid flow control unit 34 may be disposed on the high-temperature pipe 383. For example, the high-temperature fluid valve 321, the high-temperature fluid tank 33, and the high-temperature fluid flow control unit 34 may be disposed in series on the high-temperature pipe 383. The high-temperature fluid flow control unit 34 may be a high-temperature fluid flow controller.

The high-temperature fluid valve 321 may control a fluid flow branched off from the first supply pipe 381. For example, the high-temperature fluid valve 321 may be open to flow a fluid through the high-temperature pipe 383 or be closed to block the fluid from flowing through the high-temperature pipe 383.

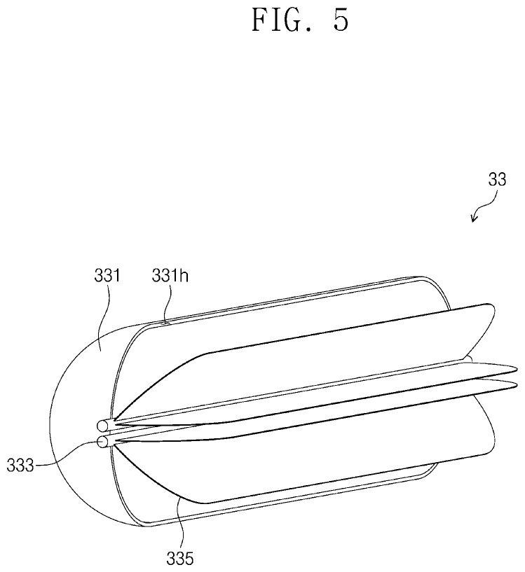

The high-temperature fluid tank 33 may store and/or heat a fluid supplied from the fluid supply tank 311. For example, the high-temperature fluid tank 33 may store a fluid flowed through a pipe (e.g., the high-temperature pipe 383) branched off from the first supply pipe 381 after passing through the pump 315. The high-temperature fluid tank 33 may control a temperature of fluid stored therein. For example, the high-temperature fluid tank 33 may maintain the stored fluid at a first temperature. The first temperature may range from about 75° C. to about 88° C. For example, the first temperature may be about 81.5° C. A fluid stored in the high-temperature fluid tank 33 may be in its supercritical state. The high-temperature fluid tank 33 will be further discussed in detail below with reference to FIG. 5. In this description, a fluid that comes from the high-temperature fluid tank 33 may be referred to as a high-temperature fluid.

The high-temperature fluid flow control unit 34 may be positioned between the high-temperature fluid tank 33 and the dry chamber A. The high-temperature fluid flow control unit 34 may adjust a flow rate of the high-temperature fluid that comes from the high-temperature fluid tank 33. The high-temperature fluid flow control unit 34 may include a first flow pipe 341 and a first flow valve 343.

The first flow pipe 341 may be connected to the high-temperature pipe 383. A plurality of first flow pipes 341 may be provided in the high-temperature fluid flow control unit 34. The plurality of first flow pipes 341 may be disposed in parallel between the high-temperature fluid tank 33 and the dry chamber A. The plurality of first flow pipes 341 may have different diameters from each other. The present inventive concepts, however, are not limited thereto, and the plurality of first flow pipes 341 may all have the same diameter. The plurality of first flow pipes 341 may be connected to the second supply pipe 387. In the following descriptions, a single first flow pipe 341 will be discussed, which represents each of the plurality of first flow pipes 341 unless otherwise specified.

The first flow valve 343 may be positioned on the first flow pipe 341. The first flow valve 343 may control a flow of the high-temperature fluid that flows through the first flow pipe 341. For example, when the first flow valve 343 is opened, the high-temperature fluid may flow through the first flow pipe 341. When the first flow valve 343 is closed, the high-temperature fluid may not flow through the first flow pipe 341. When a plurality of first flow pipes 341 is provided in the high-temperature fluid flow control unit 34, a plurality of first flow valves 343 may also be provided in high-temperature fluid flow control unit 34. The plurality of first flow valves 343 may be respectively positioned on the plurality of first flow pipes 341. In the following descriptions, a single first flow valve 343 will be discussed, which represents each of the plurality of first flow valves 343 unless otherwise specified.

The low-temperature pipe 385 may be connected to the first supply pipe 381. For example, the low-temperature pipe 385 may be branched off from the first supply pipe 381. The low-temperature pipe 385 may be disposed in parallel to the high-temperature pipe 383. For example, the low-temperature pipe 385 and the high-temperature pipe 383 may be disposed in parallel between the first supply pipe 381 and the second supply pipe 387. The low-temperature fluid valve 323, the low-temperature fluid tank 35, and the low-temperature fluid flow control unit 36 may be disposed on the low-temperature pipe 385. For example, the low-temperature fluid valve 323, the low-temperature fluid tank 35, and the low-temperature fluid flow control unit 36 may be disposed in series on the low-temperature pipe 385. The low-temperature fluid flow control unit 36 may be a low-temperature fluid flow controller.

The low-temperature fluid valve 323 may control a fluid flow branched off from the first supply pipe 381. For example, the low-temperature fluid valve 323 may be open to flow a fluid through the low-temperature pipe 385 or be closed to block the fluid from flowing through the low-temperature pipe 385.

The low-temperature fluid tank 35 may be disposed in parallel to the high-temperature fluid tank 33. For example, the low-temperature fluid tank 35 and the high-temperature fluid tank 33 may be disposed in parallel between the fluid supply tank 311 and the dry chamber A. Therefore, a fluid supplied from the fluid supply tank 311 may move to the dry chamber A through only one of the low-temperature fluid tank 35 and the high-temperature fluid tank 33. The low-temperature fluid tank 35 may store and/or heat a fluid supplied from the fluid supply tank 311. For example, the low-temperature fluid tank 35 may store a fluid branched off from the first supply pipe 381 after passing through the pump 315. The low-temperature fluid tank 35 may control a temperature of fluid stored therein. For example, the low-temperature fluid tank 35 may maintain the stored fluid at a second temperature. The second temperature may be distinguished from the first temperature. For example, the second temperature may be different from the first temperature. The second temperature may range from about 28° C. to about 38° C. For example, the second temperature may be about 33° C. A fluid stored in the low-temperature fluid tank 35 may be in its supercritical state, but the present inventive concepts are not limited thereto. For example, a fluid stored in the low-temperature fluid tank 35 may be in a liquid state or a gaseous state. In this description, a fluid that comes from the low-temperature fluid tank 35 may be referred to as a low-temperature fluid.

The low-temperature fluid flow control unit 36 may be positioned between the low-temperature fluid tank 35 and the dry chamber A. The low-temperature fluid flow control unit 36 may adjust a flow rate of the low-temperature fluid that comes from the low-temperature fluid tank 35. The low-temperature fluid flow control unit 36 may include a second flow pipe 361 and a second flow valve 363.

The second flow pipe 361 may be connected to the low-temperature pipe 385. A plurality of second flow pipes 361 may be provided in the low-temperature fluid flow control unit 36. The plurality of second flow pipes 361 may be disposed in parallel between the low-temperature fluid tank 35 and the dry chamber A. The plurality of second flow pipes 361 may have different diameters from each other. The present inventive concepts, however, are not limited thereto, and the plurality of second flow pipes 361 may all have the same diameter. The plurality of second flow pipes 361 may be connected to the second supply pipe 387. In the following descriptions, a single second flow pipe 361 will be discussed, which represents each of the plurality of second flow pipes 361 unless otherwise specified.

The second flow valve 363 may be positioned on the second flow pipe 361. The second flow valve 363 may control a flow of the low-temperature fluid that flows through the second flow pipe 361. For example, when the second flow valve 363 is opened, the low-temperature fluid may flow through the second flow pipe 361. When the second flow valve 363 is closed, the low-temperature fluid may not flow through the second flow pipe 361. When a plurality of second flow pipes 361 is provided in the low-temperature fluid flow control unit 36, a plurality of second flow valves 363 may also be provided in the low-temperature fluid flow control unit 36. The plurality of second flow valves 363 may be respectively positioned on the plurality of second flow pipes 361. In the following descriptions, a single second flow valve 363 will be discussed, which represents each of the plurality of second flow valves 363 unless otherwise specified.

The second supply pipe 387 may be connected to the high-temperature pipe 383 and the low-temperature pipe 385. The high-temperature pipe 383 and the low-temperature 385 may be connected through the second supply pipe 387 to the dry chamber A. The mixer 37, the heater 316, and the second valve 317 may be disposed on the second supply pipe 387. For example, the mixer 37, the heater 316, and the second valve 317 may be disposed in series on the second supply pipe 387.

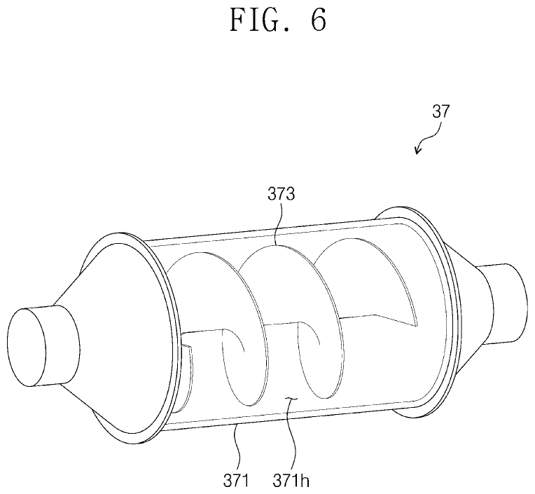

The mixer 37 may mix the high-temperature fluid with the low-temperature fluid. A fluid mixed by the mixer 37 may have a temperature less than that of the high-temperature fluid. The temperature of the fluid mixed by the mixer 37 may be greater than that of the low-temperature fluid. The mixer 37 may include, for example, a static mixer. A detailed description of the mixer 37 will be further discussed below with reference to FIG. 6.

The heater 316 may heat a fluid that moves along the second supply pipe 387. A fluid that has passed through the heater 316 may be in its supercritical state. The second valve 317 may control a flow of fluid that flows through the second supply pipe 387. For example, the second valve 317 may be open to flow a fluid through the second supply pipe 387 or be closed to block the fluid from flowing through the second supply pipe 387. A fluid mixed in the mixer 37 may be supplied through the second valve 317 to the dry chamber A. A fluid supplied to the dry chamber A may be referred to as a dry fluid.

FIG. 5 illustrates an exploded perspective view showing a high-temperature fluid tank according to some embodiments of the present inventive concepts.

Referring to FIG. 5, the high-temperature fluid tank 33 may include a tank housing 331, a heating device 333, and a heat transfer plate 335.

The tank housing 331 may provide a reservoir space 331h. The reservoir space 331h may be connected to the high-temperature pipe (see 383 of FIG. 4). The tank housing 331 may provide one or more of an inlet and an outlet (not shown).

At least a portion of the heating device 333 may be positioned in the tank housing 331. For example, the heating device 333 may penetrate through the tank housing 331. The heating device 333 may heat a fluid present in the reservoir space 331h. For example, the heating device 333 may heat and/or maintain a temperature of a fluid in the reservoir space 331h. The heating device 333 may include or may be a hot wire and so forth. For example, the heating device 333 may include one or more of a copper hot wire and a chromium hot wire. The present inventive concepts, however, are not limited thereto, and the heating device 333 may heat a fluid in other ways. A plurality of heating devices 333 may be provided in the high-temperature fluid tank 33. For example, as shown in FIG. 5, two heating devices 333 may be provided in the high-temperature fluid tank 33. In this description, a single heating device 333 will be discussed below, which represents each of the heating devices 333 unless otherwise specified.

The heat transfer plate 335 may be positioned in the tank housing 331. The heat transfer plate 335 may be connected to the heating device 333. The heat transfer plate 335 may disperse heat supplied from the heating device 333 throughout the heat transfer plate 335 and transfer the heat to the fluid in the high-temperature fluid tank 33. The heating device 333 may effectively heat a fluid present in the reservoir space 331h. A plurality of heat transfer plates 335 may be provided in the high-temperature fluid tank 33. As shown in FIG. 5, the plurality of heat transfer plates 335 may be spaced apart from each other in a circumferential direction. A single heat transfer plate 335, however, will be discussed below, which represents each of the plurality of heat transfer plates 335 unless otherwise specified.

Although not shown, the low-temperature fluid tank (see 35 of FIG. 4) may include or be formed of the same components as the ones of the high-temperature fluid tank 33 with a configuration the same as or similar to that of the high-temperature fluid tank 33.

FIG. 6 illustrates a perspective view showing a mixer according to some embodiments of the present inventive concepts.

Referring to FIG. 6, the mixer 37 may include a mixer housing 371 and a blade 373. The mixer hosing 371 may provide a mixing space 371h, e.g., enclosed by the mixer housing 371. The mixing space 371h may be connected to the second supply pipe (see 387 of FIG. 4). The blade 373 may be positioned in the mixing space 371h. When the mixer 37 is a static mixer, the blade 373 may be fixed on a certain location. For example, the blade 373 may not move while a fluid is flowing through the mixer 37 and the fluid is mixed by the blade 373, e.g., by a turbulence formed in the fluid by the blade 373. The present inventive concepts, however, are not limited thereto, and the blade 373 may be rotatable.

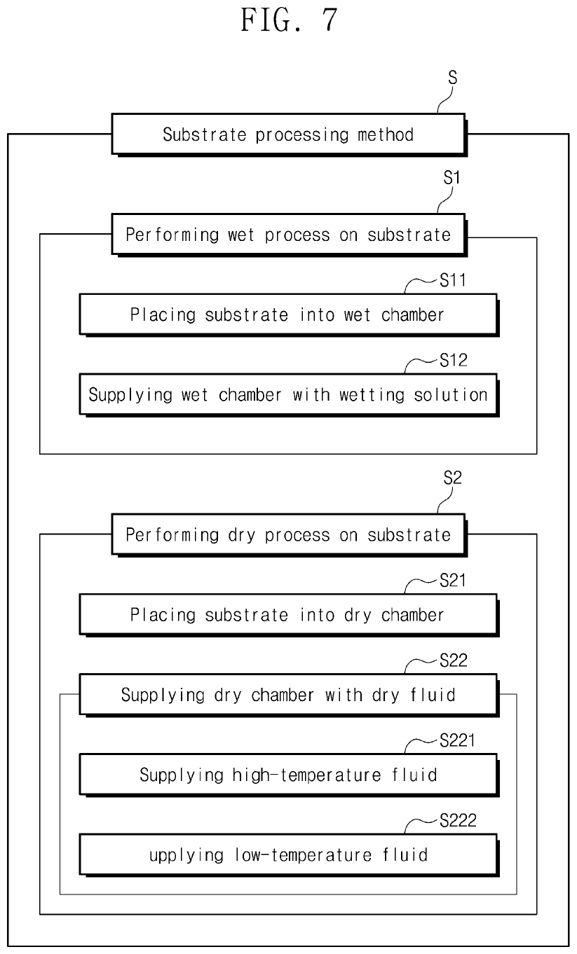

FIG. 7 illustrates a flow chart showing a substrate processing method according to some embodiments of the present inventive concepts.

Referring to FIG. 7, a substrate processing method S may be provided. The substrate processing method S may be a method to treat a substrate by using the substrate processing apparatus (see P of FIG. 1) discussed with reference to FIGS. 1 to 6. The substrate processing method S may include performing a wet process on a substrate (S1) and performing a dry process on the substrate (S2).

The substrate wetting step S1 may include placing a substrate into a wet chamber (S11) and supplying the wet chamber with a wetting solution (S12), e.g., to treat the substrate with the wetting solution.

The substrate drying step S2 may include placing the substrate into a dry chamber (S21) and supplying the dry chamber with a dry fluid (S22), e.g., to treat the substrate with the dry fluid.

The dry fluid supply step S22 may include supplying a high-temperature fluid (S221) and supplying a low-temperature fluid (S222).

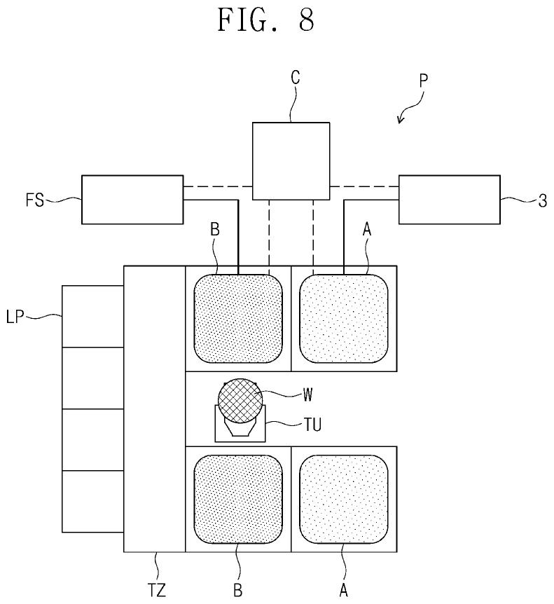

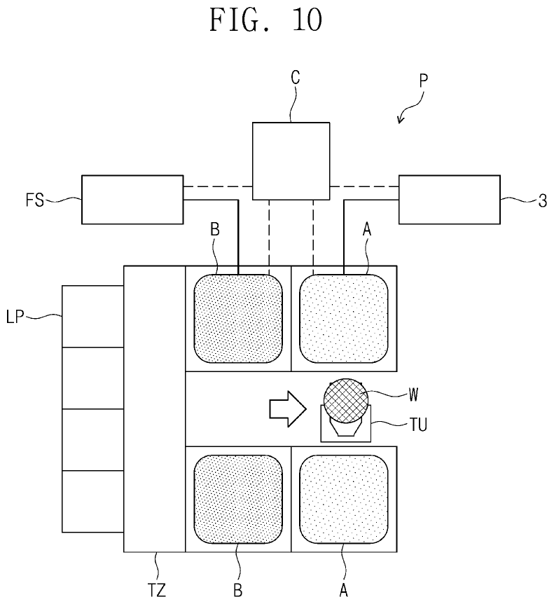

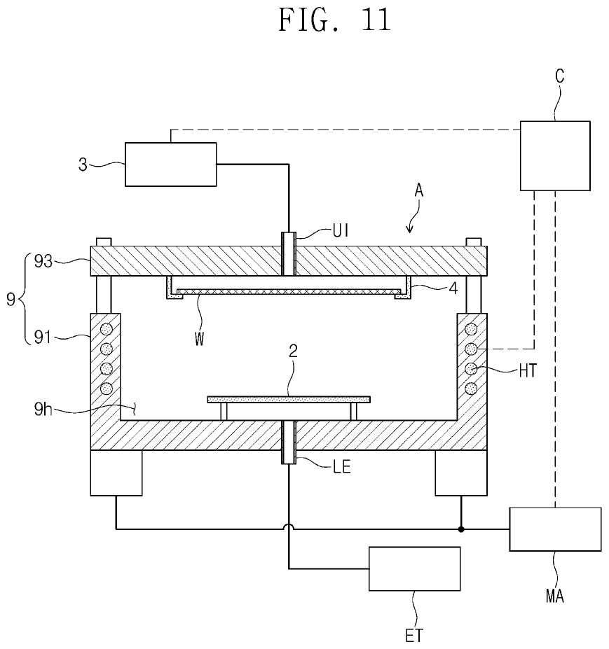

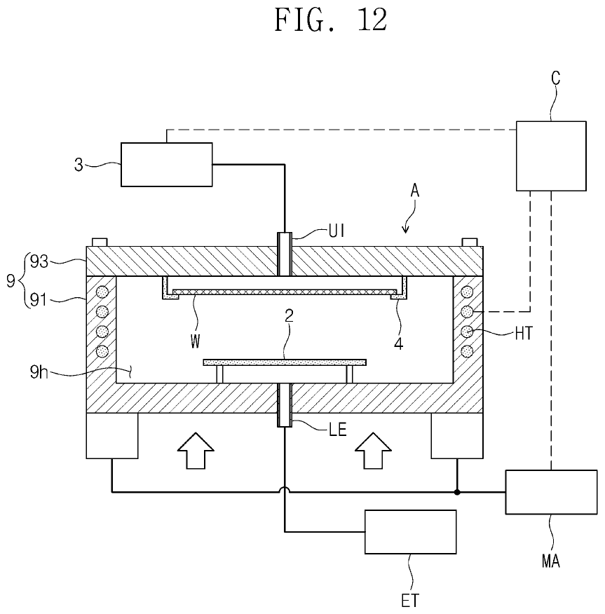

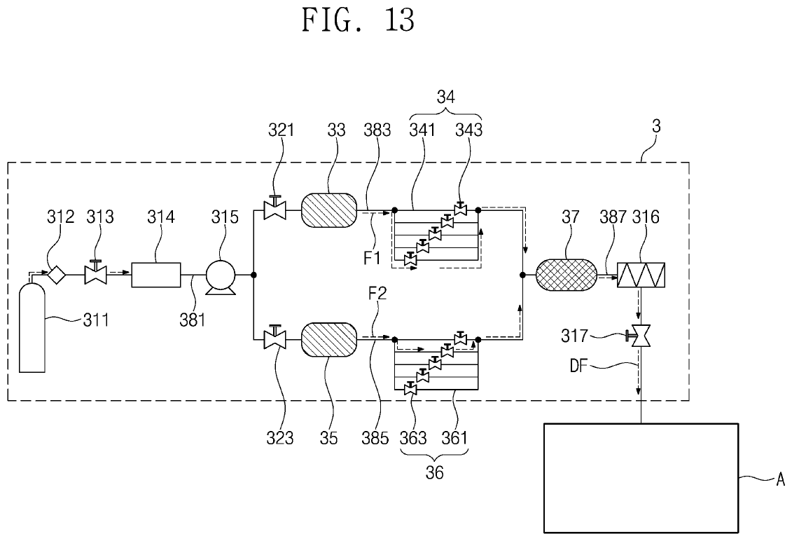

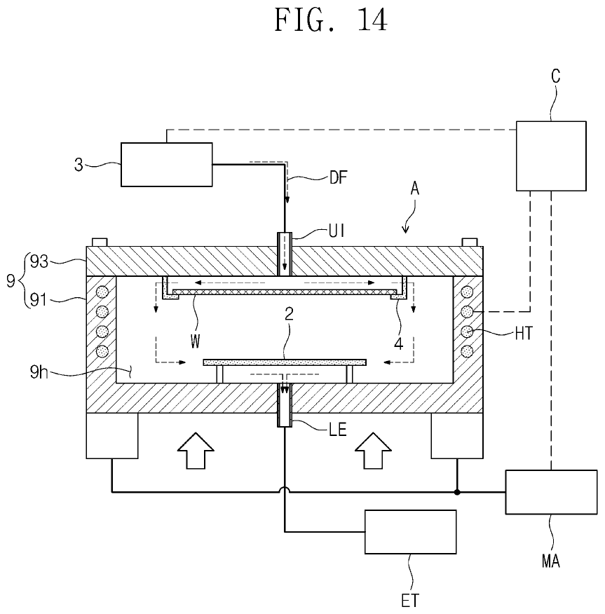

With reference to FIGS. 8 to 14, the following will describe the substrate processing method S of FIG. 7.

FIGS. 8 to 14 illustrate diagrams showing a substrate processing method according to the flow chart of FIG. 7.

Referring to FIGS. 7, 8, and 9, the substrate placement step S11 may include placing a substrate W on the wetting stage 73 of the wet chamber B. The substrate W may be disposed below the wetting nozzle 75.

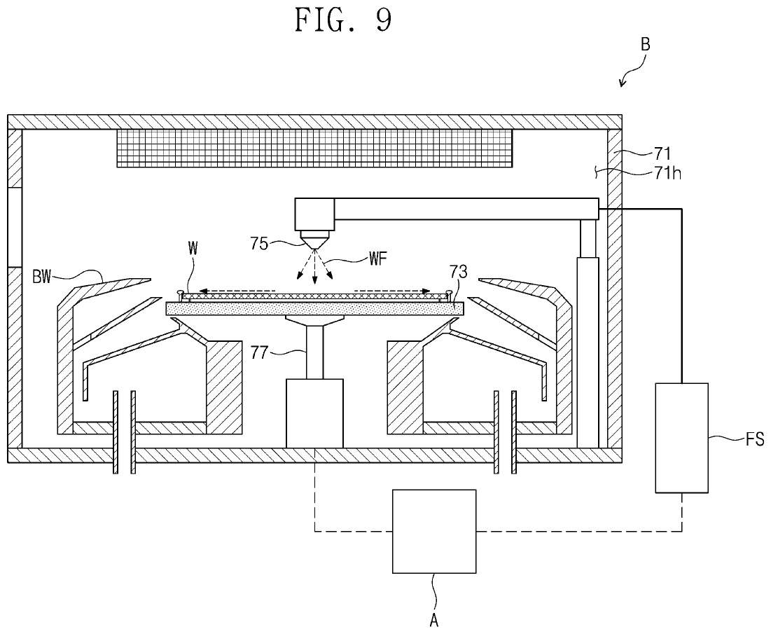

Referring to FIGS. 7 and 9, the wetting solution supply step S12 may include allowing the wetting space 71h to receive a wetting solution WF supplied from the wetting solution supply apparatus FS in a state where the substrate W is disposed on the wetting stage 73. For example, the wetting solution WF may be sprayed through the wetting nozzle 75 onto the substrate W. As discussed above, the wetting solution WF may include or may be a developer or isopropyl alcohol (IPA). In this procedure, the rotating shaft 77 may rotate the wetting stage 73, thereby rotating the substrate W. Therefore, the sprayed wetting solution WF may be uniformly spread out on the substrate W. When the substrate W rotates, a portion of the wetting solution WF may be scattered toward the bowl BW. The wet chamber B may unload the substrate W that has experienced (e.g., been processed with) the wet process.

Referring to FIGS. 7, 10, 11, and 12, the substrate placement step S21 may include allowing the dry chamber A to receive the substrate W that has been processed in the wet chamber. For example, the substrate W may be disposed on the dry chuck 4. The upper chamber 93 and the lower chamber 91 may approach each other in a state where the substrate W is disposed on the dry chuck 4. Therefore, the dry space 91 may be separated from external environment.

Referring to FIGS. 7, 13, and 14, the high-temperature fluid supply step S221 may include supplying a high-temperature fluid F1 from the high-temperature fluid tank 33 to the second supply pipe 387 and to the mixer 37. A fluid supplied from the fluid supply tank 311 may be heated and/or stored in the high-temperature fluid tank 33, and if necessary, the fluid may then be supplied to the mixer 37 through the high-temperature fluid flow control unit 34. The controller C may control the high-temperature fluid flow control unit 34 to adjust a flow of the high-temperature fluid F1 supplied from the high-temperature fluid tank 33. For example, the controller C may control each of a plurality of first flow valves 343, such that a flow of the high-temperature fluid F1 supplied from the high-temperature fluid tank 33 may be adjusted to have a first flow rate. In order to achieve the first flow rate of the high-temperature fluid F1, one or more of the plurality of first flow valves 343 may be opened, and one or more others of the plurality of first flow valves 343 may be closed. Therefore, the high-temperature fluid F1 having the first temperature may be introduced at the first flow rate into the mixer 37.

The low-temperature fluid supply step S222 may include supplying a low-temperature fluid F2 from the low-temperature fluid tank 35 to the second supply pipe 387 and to the mixer 37. A fluid supplied from the fluid supply tank 311 may be heated and/or stored in the low-temperature fluid tank 35, and if necessary, the fluid may then be supplied to the mixer 37 through the low-temperature fluid flow control unit 36. The controller C may control the low-temperature fluid flow control unit 36 to adjust a flow of the low-temperature fluid F2 supplied from the low-temperature fluid tank 35. For example, the controller C may control each of a plurality of second flow valves 363, such that a flow of the low-temperature fluid F2 supplied from the low-temperature fluid tank 35 may be adjusted to have a second flow rate. In order to achieve the second flow rate of the low-temperature fluid F2, one or more of the plurality of second flow valves 363 may be opened, and one or more others of the plurality of second flow valves 363 may be closed. Therefore, the low-temperature fluid F2 having the second temperature may be introduced at the second flow rate into the mixer 37.

The dry fluid supply step S22 may further include mixing the high-temperature fluid F1 and the low-temperature fluid F2 with each other. For example, the high-temperature fluid F1 and the low-temperature fluid F2 may be mixed with each other to enter the dry chamber A. A fluid formed by the mixing of the high-temperature fluid F1 and the low-temperature fluid F2 may be referred to as a dry fluid DF. For example, the high-temperature fluid F1 and the low-temperature fluid F2 may be mixed with each other in the mixer 37. The present inventive concepts, however, are not limited thereto, and the high-temperature fluid F1 and the low-temperature fluid F2 may be mixed with each other in the second supply pipe 387, e.g., without providing the mixer 37 on the second supply pipe 387. The dry fluid DF may be supplied to the dry chamber A. The dry fluid DF supplied to the dry chamber A may be in its supercritical state. For example, the dry fluid DF supplied to the dry chamber A may be a supercritical fluid.

The dry fluid DF supplied to the dry chamber A may remove a liquid on the substrate W. For example, the dry fluid DF may substitute for a liquid on the substrate W, thereby removing the liquid from the substrate W. The dry fluid DF may be discharged through the fluid exhaust outlet LE.

In some embodiments, the substrate drying step S2 may further include determining the first flow rate and the second flow rate based on the type of substrate disposed in the dry chamber A. An adjustment of each of the first flow rate and second flow rate may control/change a temperature and/or a flow rate of the dry fluid DF supplied to the dry chamber A. For example, an increase in the first flow rate may increase the temperature of the dry fluid DF. An increase in the second flow rate may lower the temperature of the dry fluid DF. When a temperature of the dry fluid DF depends on type of substrate and/or on a previous process performed in the wet chamber B, the controller C may analyze this situation to determine each of the first flow rate and the second rate.

In some embodiments, the dry fluid supply step S22 may further include changing a flow rate of the high-temperature fluid F1 supplied from the high-temperature fluid tank 33 while a dry process is performed on the substrate W. The controller C may use the high-temperature fluid flow control unit 34 to change the first flow rate to a different flow rate of the high-temperature fluid F1 supplied from the high-temperature fluid tank 33. For example, a flow rate of the high-temperature fluid F1 may be changed/controlled by adjusting/setting the plurality of first flow valves 343 to their open or closed states. When the high-temperature fluid F1 is adjusted in its flow rate, it may be possible to change a temperature of the dry fluid DF formed by the mixing of the high-temperature fluid F1 and the low-temperature fluid F2. Therefore, the substrate W may be provided thereon with the dry fluid DF whose temperature is changed. It is described above that a flow rate of the high-temperature fluid F1 is changed to change/adjust the temperature of the dry fluid DF, but this description may be applicable to change a flow rate of the low-temperature fluid F2. For example, the flow rate of the low-temperature fluid F2 may be changed/adjusted to change the temperature of the dry fluid DF.

According to a supercritical fluid supply apparatus, a substrate processing apparatus including the same, and a substrate processing method using the same according to some embodiments of the present inventive concepts, a dry fluid may be formed by mixing a high-temperature fluid and a low-temperature fluid with each other. A temperature of the dry fluid may be controlled by adjusting a flow rate of the high-temperature fluid and a flow rate of the low-temperature fluid. Therefore, it may be possible to promptly change the temperature of the dry fluid. The prompt change in temperature of the dry fluid may be applied in the middle of execution/performance of processes, which is beneficial in that a wide choice of processes is available in drying substrates.

According to a supercritical fluid supply apparatus, a substrate processing apparatus including the same, and a substrate processing method using the same according to some embodiments of the present inventive concepts, because it is possible to promptly change the temperature of the dry fluid, the temperature of the dry fluid may be changed to cope with recipes which are different for different substrates.

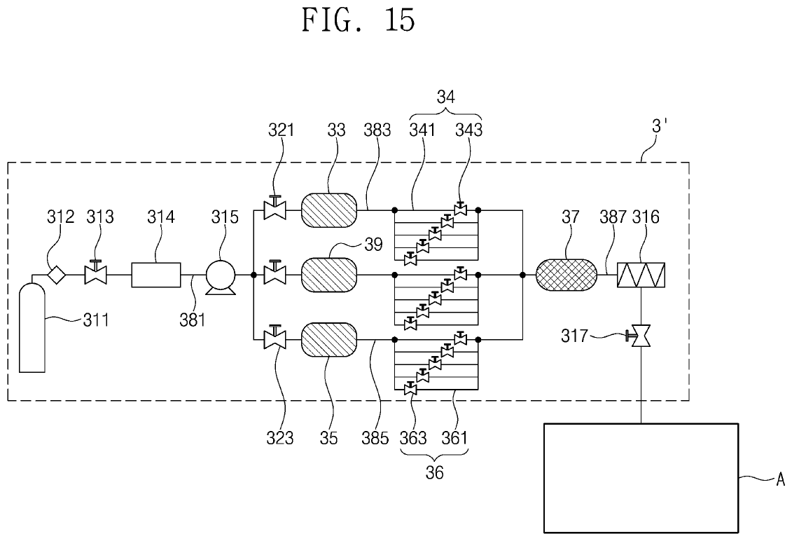

FIG. 15 illustrates a simplified schematic diagram showing a supercritical fluid supply apparatus according to some embodiments of the present inventive concepts.

The following will omit descriptions of components the same as those discussed with reference to FIGS. 1 to 14.

Referring to FIG. 15, a supercritical fluid supply apparatus 3′ may further include a middle-temperature fluid tank 39. The middle-temperature fluid tank 39 may be disposed in parallel to the high-temperature fluid tank 33 and the low-temperature fluid tank 35. For example, the high-temperature fluid tank 33, the middle-temperature fluid tank 39, and the low-temperature fluid tank 35 may be disposed in parallel between the fluid supply tank 311 and the dry chamber A.

According to a supercritical fluid supply apparatus, a substrate processing apparatus including the same, and a substrate processing method using the same according to some embodiments of the present inventive concepts, a temperature of fluid supplied from a fluid supply tank may be changed into three different temperatures in the high-temperature fluid tank 33, the middle-temperature fluid tank 39 and the low-temperature fluid tank 35 respectively, and three fluids having different temperatures may be stored separately from each other in the respective high-temperature fluid tank 33, middle-temperature fluid tank 39 and low-temperature fluid tank 35. Accordingly, it may be possible to precisely control a temperature of dry fluid by mixing proper amounts of respective fluids, e.g., by adjusting flow rates of the respective fluids having different temperatures.

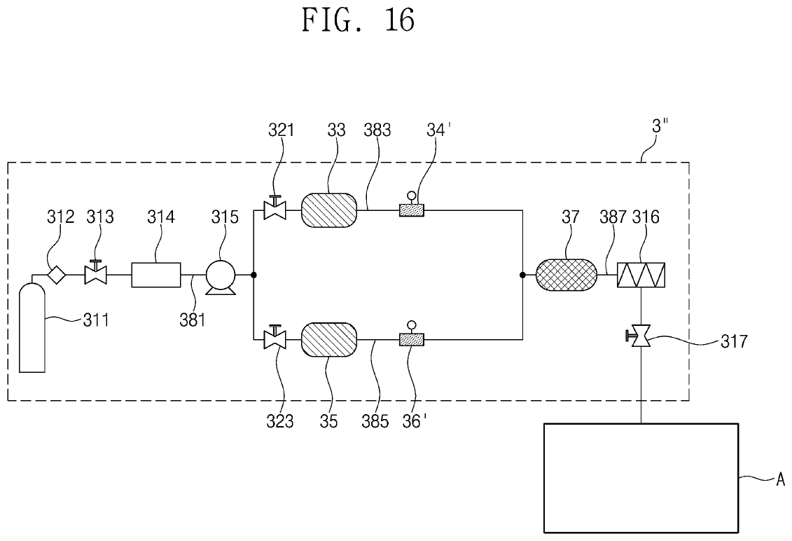

FIG. 16 illustrates a simplified schematic diagram showing a supercritical fluid supply apparatus according to some embodiments of the present inventive concepts.

The following will omit descriptions of components the same as those discussed with reference to FIGS. 1 to 15.

Referring to FIG. 16, one or both of the high-temperature fluid flow control unit 34′ and the low-temperature fluid flow control unit 36′ may include or may be a gas flow controller (GFC). For example, as shown in FIG. 16, one or both of the high-temperature fluid flow control unit 34 and the low-temperature fluid flow control unit 36 may not include a plurality of pipes and/or a plurality of valves.

According to a supercritical fluid supply apparatus, a substrate processing apparatus including the same, and a substrate processing method using the same according to some embodiments of the present inventive concepts, it may be possible to adjust a fluid flow with simple equipment.

According to a supercritical fluid supply apparatus, a substrate processing apparatus including the same, and a substrate processing method using the same according to some embodiments of the present inventive concepts, it may be possible to promptly control/adjust the temperature of a supercritical fluid.

According to a supercritical fluid supply apparatus, a substrate processing apparatus including the same, and a substrate processing method using the same according to some embodiments of the present inventive concepts, it may be possible to change the temperature of a supercritical fluid supplied in the middle of execution of processes.

According to a supercritical fluid supply apparatus, a substrate processing apparatus including the same, and a substrate processing method using the same according to some embodiments of the present inventive concepts, it may be possible to quickly cope with various recipes.

Even though different figures show variations of exemplary embodiments and different embodiments disclose different features from each other, these figures and embodiments are not necessarily intended to be mutually exclusive from each other. Rather, certain features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally unless the context indicates otherwise.

Effects of the present inventive concepts are not limited to the ones mentioned above, other effects which have not been mentioned above will be clearly understood to those skilled in the art from the description.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A substrate processing apparatus, comprising:
a dry chamber including a dry space configured in which to dispose a substrate; and
a supercritical fluid supply apparatus configured to supply the dry chamber with a supercritical fluid,
wherein the supercritical fluid supply apparatus includes:
a fluid supply tank;
a high-temperature fluid tank configured in which to store a fluid supplied from the fluid supply tank at a first temperature; and
a low-temperature fluid tank configured in which to store a fluid supplied from the fluid supply tank at a second temperature different from the first temperature,
wherein the high-temperature fluid tank and the low-temperature fluid tank are connected in parallel between the fluid supply tank and the dry chamber.

2. The substrate processing apparatus of claim 1, wherein the supercritical fluid supply apparatus further includes a mixer configured to mix a fluid coming from the high-temperature fluid tank with a fluid coming from the low-temperature fluid tank,
wherein the mixer includes:
a mixer housing that provides a mixing space; and
a blade fixed in the mixer housing.

3. The substrate processing apparatus of claim 1, wherein the high-temperature fluid tank includes:
a tank housing that provides a reservoir space; and
a heating device in the tank housing.

4. The substrate processing apparatus of claim 3, wherein the high-temperature fluid tank further includes a heat transfer plate in the tank housing and connected to the heating device.

5. The substrate processing apparatus of claim 1, wherein the supercritical fluid supply apparatus further includes:
a high-temperature fluid flow controller between the high-temperature fluid tank and the dry chamber, the high-temperature fluid flow controller configured to adjust a flow rate of a fluid that comes from the high-temperature fluid tank; and
a low-temperature fluid flow controller between the low-temperature fluid tank and the dry chamber, the low-temperature fluid flow controller configured to adjust a flow rate of a fluid that comes from the low-temperature fluid tank.

6. The substrate processing apparatus of claim 5, wherein the high-temperature fluid flow controller includes:
a plurality of first flow pipes that are connected in parallel between the high-temperature fluid tank and the dry chamber; and
a plurality of first flow valves on respective first flow pipes.

7. The substrate processing apparatus of claim 1, wherein the supercritical fluid supply apparatus further includes:
a condenser connected to the fluid supply tank; and
a pump connected to the condenser,
wherein the fluid supply tank, the condenser, and the pump are in series with each other, and
wherein the high-temperature fluid tank and the low-temperature fluid tank are between the pump and the dry chamber.

8. The substrate processing apparatus of claim 1, wherein the dry chamber includes a dry chuck configured on which to fix the substrate in the dry space.

9. The substrate processing apparatus of claim 1, further comprising:
a wet chamber configured in which to perform a wet process on the substrate; and
a fluid supply apparatus configured to supply the wet chamber with a wetting solution,
wherein the dry chamber is configured to perform a dry process on the substrate that has been processed in the wet chamber.

10. A supercritical fluid supply apparatus, comprising:
a fluid supply tank;
a condenser connected to the fluid supply tank;
a pump connected to the condenser;
a high-temperature fluid tank connected to the pump;
a low-temperature fluid tank connected to the pump; and
a mixer configured to mix a fluid coming from the high-temperature fluid tank with a fluid coming from the low-temperature fluid tank,
wherein the fluid supply tank, the condenser, and the pump are connected in series with each other,
wherein the high-temperature fluid tank and the low-temperature fluid tank are connected in parallel between the pump and the mixer,
wherein the high-temperature fluid tank is configured to store a fluid supplied from the fluid supply tank at a first temperature, and
wherein the low-temperature fluid tank is configured to store a fluid supplied from the fluid supply tank at a second temperature, the second temperature being different from the first temperature.

11. The supercritical fluid supply apparatus of claim 10, further comprising:
a high-temperature fluid flow controller between the high-temperature fluid tank and the mixer; and
a low-temperature fluid flow controller between the low-temperature fluid tank and the mixer.

12. The supercritical fluid supply apparatus of claim 10, wherein the mixer includes:
a mixer housing that provides a mixing space; and
a blade fixed in the mixer housing.

13. The supercritical fluid supply apparatus of claim 10, wherein the high-temperature fluid tank includes:
a tank housing that provides a reservoir space;
a heating device in the tank housing; and
a heat transfer plate connected to the heating device in the tank housing.

14. A substrate processing method, comprising:
performing a wet process on a substrate; and
performing a dry process on the substrate that has been processed with the wet process,
wherein performing the dry process on the substrate includes:
placing the substrate into a dry chamber; and
supplying the dry chamber with a dry fluid from a supercritical fluid supply apparatus,
wherein supplying the dry chamber with the dry fluid includes:
supplying a high-temperature fluid from a high-temperature fluid tank;
supplying a low-temperature fluid from a low-temperature fluid tank; and
supplying the dry chamber with the dry fluid formed by mixing the high-temperature fluid and the low-temperature fluid with each other.

15. The substrate processing method of claim 14, wherein supplying the dry chamber with the dry fluid includes using a mixer to mix the high-temperature fluid and the low-temperature fluid with each other.

16. The substrate processing method of claim 15, wherein performing the dry process on the substrate includes, in the middle of supplying the dry fluid to the substrate in the dry chamber, changing a flow rate of the high-temperature fluid supplied from the high-temperature fluid tank.

17. The substrate processing method of claim 14, wherein
supplying the high-temperature fluid from the high-temperature fluid tank includes supplying the high-temperature fluid at a first flow rate, and
supplying the low-temperature fluid from the low-temperature fluid tank includes supplying the low-temperature fluid at a second flow rate.

18. The substrate processing method of claim 17, wherein performing the dry process on the substrate includes, before supplying the dry chamber with the dry fluid, determining each of the first flow rate and the second flow rate based on a type of the substrate disposed in the dry chamber.

19. The substrate processing method of claim 14, wherein
the high-temperature fluid tank heats a fluid supplied from a fluid supply tank to a first temperature and stores the heated fluid, and
the low-temperature fluid tank heats a fluid supplied from the fluid supply tank to a second temperature less than the first temperature.

20. The substrate processing method of claim 19, wherein
the first temperature ranges from about 75° C. to about 88° C., and
the second temperature ranges from about 28° C. to about 38° C.
